(19) United States
(12) Patent Application Publication
(10) Pub. No.: US 2008/0273316 A1
(43) Pub. Date: Nov. 6, 2008

(54) Lightweight Rigid Case for Electronic Apparatus

(75) Inventors: Claude Sarno, Etoile/Sur/Rhone (FR); Christophe Jarnias, Valence (FR); Pierre Marfisi, Chabeuil (FR)

Correspondence Address: LOWE HAUPTMAN & BERNER, LLP, 1700 DIAGONAL ROAD, SUITE 300, ALEXANDRIA, VA, 22314, US

(73) Assignee: Thales, Neuilly/Sur/Seine (FR)

(21) Appl. No.: 12/066,429

(22) PCT Filed: Nov. 22, 2006
(86) PCT No.: PCT/EP2006/068735

§ 371 Date: Mar. 11, 2008

(30) Foreign Application Priority Data
Dec. 7, 2005 (FR) 0512425

(51) Int. Cl. H05K 7/14

(52) U.S. Cl. 361/807

(57) ABSTRACT

The field of the invention is that of electronic apparatus cases and more particularly electronic apparatus cases with which carriers, especially aircraft, are equipped. The electronic apparatus case comprises metal walls (101), (102), (103), (104) that are mounted on reinforcements, the reinforcements comprising two frames (111), (112) and four cross-members (113), (114), (115), (116) of identical length connecting the two frames (111), (112). According to the invention, the frames (111), (112) are made of cast magnesium alloy, molded and/or machined, and in that at least one of the walls (101), (102), (103), (104) is made from a sheet of magnesium alloy.

### CROSS-REFERENCE TO RELATED APPLICATIONS

The present Application is based on International Application No. PCT/EP2006/068735, filed on Nov. 22, 2006, which in turn corresponds to French Application No. 05 12425, filed on Dec. 7, 2005, and priority is hereby claimed under 35 USC §119 based on these applications. Each of these applications are hereby incorporated by reference in their entirety into the present application.

### FIELD OF THE INVENTION

The field of the invention is that of electronic apparatus cases and more particularly electronic apparatus cases with which carriers, especially aircraft, are equipped.

### BACKGROUND OF THE INVENTION

Electronic equipment items are mounted in a very large number on board aircraft in order to fulfil many functions. Most often, these equipment items are distributed within the aircraft in a modular architecture, facilitating both their design and their interchangeability. In this type of architecture, the modules are sets of electronic apparatus, for example printed circuit cards, the faces of which bear electronic components, said modules being housed inside a cavity formed by a case, frequently made of metal and of parallelepipedal shape. Firstly, the case ensures that the electronic apparatus is housed and guided inside the cavity and secondly, the case is shaped so as to be mechanically fastened, for example in a removable manner, to a receiving rack placed, for this purpose, on the carrier. The rigidity of the case protects the electronic apparatus, sheltering it from the harsh vibration environment. The case also provides, by its walls that form a Faraday cage, protection against the electromagnetic interference environment encountered within carriers during operation. It also prevents the electronic apparatus inside the case from disturbing equipment items placed outside the case.

In the field of civil or military aircraft, the cases and receiving racks usually meet predetermined standards according to the aircraft manufacturers' requirements. The standards normally used are ARINC 600, ARINC 650 and AER 300 or other standards specific to each aircraft manufacturer. These standards specify the dimensions to be respected by electronic apparatus cases and their mechanical interfaces, their electrical interfaces and the positions and sizes of openings appearing in certain walls of the cases. The aircraft manufacturer chooses a standard and consequently equips the carrier with the receiving rack that meets this standard.

In general, the cases meeting the ARINC or AER standards are produced by assembling folded aluminum sheet parts. The rigidity of such cases is sufficient given the low level of mechanical stresses encountered in the civil aviation field. The level of environmental stresses encountered in the field of military aircraft is in general more severe and requires greater rigidity of the walls of the case than that obtained by assembling sheet metal parts. This requirement is met by producing bulk structures made of aluminum alloy that are obtained by a casting process or by machining in bulk metal.

High performance characteristics in terms of heat dissipation, rigidity and electromagnetic protection make it possible for the cases to provide all the on-board electronic apparatus sets that they contain with packaging that guarantees survival in the environments encountered under operational conditions. The aim, in addition to equipping both civil and military aircraft, is to produce cases that are lightweight, hence, given the very large number of items of electronic apparatus on board an aircraft, the combined mass of the cases an aircraft contains may amount to several tens of kilograms, for example 30 to 40 kg on a military helicopter. Any action with a view to reducing the mass of the cases is reflected in a precious lightening of the aircraft, which may be operatively reallocated to the incorporation of new on-board functions or may be used to improve the performance of the carrier (reduced fuel consumption, extending radius of action, etc.).

To produce lightweight cases, a first approach is to reduce the thickness of the walls of the cases according to the prior art, which is in general 2 millimetres. This constitutes an average thickness, which is difficult to reduce with an aluminum alloy. A second approach consists in using innovative low-density materials in order to substitute them for the aluminum alloys employed in the prior art.

The mass-lightening approach, by reducing the wall thickness of the case, for example to reduce a wall thickness from 2 to 1.5 millimetres, requires the use of materials having a density equivalent to that of aluminum (dₐₗᵤₘᵢₙᵤₘ≈2.7) and having a Young's modulus at least twice as high as that of aluminum, that is to say greater than 150 GPa, so as to maintain an equivalent rigidity in the main retention areas of the cases (corners, mechanical attachment points, etc.). Metal matrix composites (MMCs), such as for example those with an aluminum alloy matrix filled with silicon carbide (Al/SiC), are materials that meet these criteria, but they prove to be difficult to use for economic reasons (to produce thin-walled parts is very expensive) and for mechanical reasons (their ductility makes them incompatible with the thermal and vibration environments encountered in the field of aeronautical use).

The weight-saving approach, by density reduction, means using magnesium alloys, which have mechanical properties similar to those of aluminum, in particular a rigidity close to that of aluminum (a Young's modulus of 45 GPa for magnesium alloys compared with 70 GPa for aluminum). Thus, by keeping the same wall thickness as that of the cases of the prior art, it is possible to produce electronic apparatus cases that are lighter than those of the prior art.

However, a case possessing a structure similar to that of the cases of the prior art with which civil aircraft are equipped (formed by assembling folded aluminum alloy sheet parts) with magnesium sheet parts of the same thickness would however not have sufficient rigidity to meet the aeronautical environment standards. With this structure, only by thickening the magnesium alloy sheet parts would satisfactory rigidity be achieved, but this cancels out the lightening provided by the use of a material less dense than aluminum.

Moreover, a case for possessing a structure similar to that of the cases of the prior art with which military aircraft are equipped (produced by molding by lost-wax casting or by machining in bulk metal) proves very difficult to produce. This is because the castability of magnesium alloys in the liquid state is inferior to that of molten aluminum, to the detriment of producing parts for a thin-walled case by a molding method. Moreover, since the Young's modulus of magnesium is less than that of aluminum, the rigidity of a magnesium case is inferior to that of an identical aluminum case, even produced by casting. Finally, magnesium alloys are difficult to machine for two main reasons:
there is a risk of magnesium catching fire when machining it if special precautions are not taken; and
there are residual strains in thin walls owing to the crystalline structure of magnesium.

### OBJECTS AND SUMMARY OF THE INVENTION

The object of the invention is to alleviate these drawbacks. More precisely, the aim of the invention is to produce cases for electronic apparatus that are made of a material less dense than aluminum alloys such as magnesium alloys, by modifying, in order to do this, the structure of the case compared with that of the cases of the prior art. By doing so the invention results in a novel case structure being adopted. This novel structure separates the constituents of a case into two types:
reinforcements, produced by casting and/or machining a first metallic material, the reinforcements providing the case with rigidity; and
walls, produced from sheets of a second metallic material, these providing a weight saving.

More precisely, the subject of the invention is a case for electronic apparatus comprising metal walls that are mounted on reinforcements, the reinforcement comprising two frames and four cross-members of identical length that connect the two frames characterized in that the frames are made of cast magnesium alloy, which is molded and/or machined, and in that at least one of the walls is made from a magnesium alloy sheet.

The invention makes it possible to produce electronic apparatus cases that are compatible with the thermal, electromagnetic and vibration environments encountered on board aircraft, both civil and military, by achieving a lightening of about 30% by weight relative to the cases of the prior art.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1a shows an electronic apparatus case according to the prior art with which a military aircraft is equipped;

FIG. 1b shows an electronic apparatus case according to the prior art, with which a civil aircraft is equipped;

FIG. 2 shows an electronic apparatus case according to the invention;

FIG. 3a shows an exploded view of an electronic apparatus case according to the invention; and

FIG. 3b shows a semi-exploded view of an electronic apparatus case according to the invention.

### DETAILED DESCRIPTION OF THE DRAWINGS

From one figure to another, the same elements are identified by the same references.

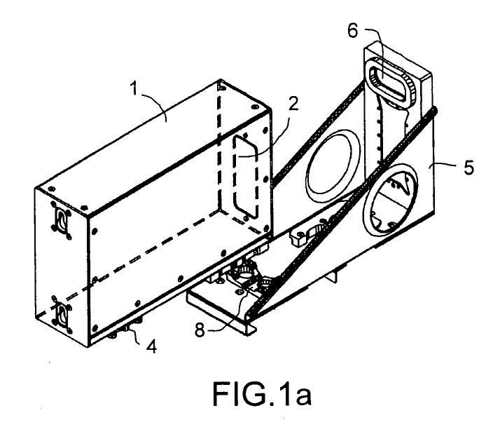

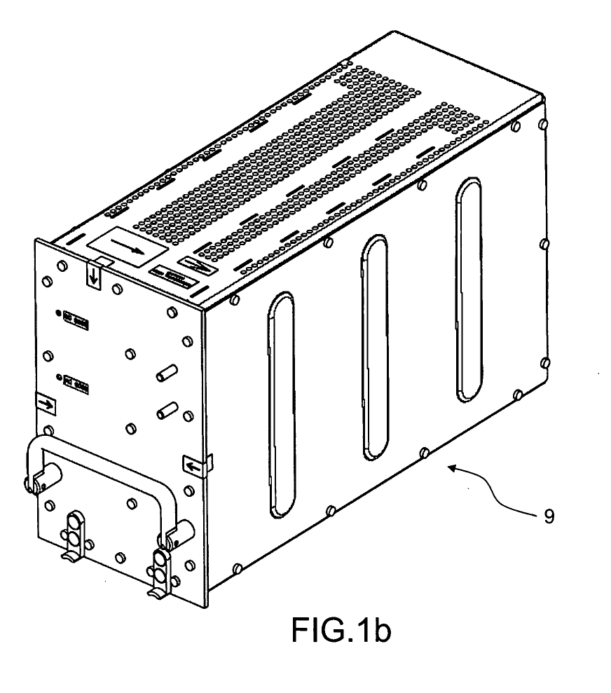

FIG. 1a shows an electronic apparatus case according to the prior art, currently employed in aeronautics, for example to produce computers on board aircraft that can withstand a harsh environment, for example aircraft of the military type or helicopters. The case 1 has a parallelepipedal shape, having, on one of its faces, a rectangular opening 2 into which a first electrical connector (not shown) can be plugged. The case 1 on another of its faces has fastening means 4.

A receiving rack 5, which also meets the AER 300 standard, is fastened to the structure of an aircraft (not shown in the figure). The rack 2 has a rectangular opening 6 into which a second electrical connector (not shown) complementary to the first connector can be plugged, and fastening means 8 complementary to the fastening means 4. The case 1 meets the AER 300 standard, which defines the dimensions of the case and the position and dimensions of the opening 2.

The case 1 may be anchored in the rack 5. The anchoring may be locked by imbrication of the fastening means 4 and 8. The anchoring is removable. The case 1 is produced either by casting or by machining aluminum for the harshest applications or made of self-stiffened sheet.

FIG. 1b shows a perspective view of an electronic apparatus case 9 of modular type, made of folded sheets of aluminum alloy with a thickness of about 2 millimetres. The sheets have sufficient rigidity to withstand the relatively low levels of mechanical stresses encountered in the civil aviation field. The rack is made of a metallic material, which may be different from the material constituting the case 1.

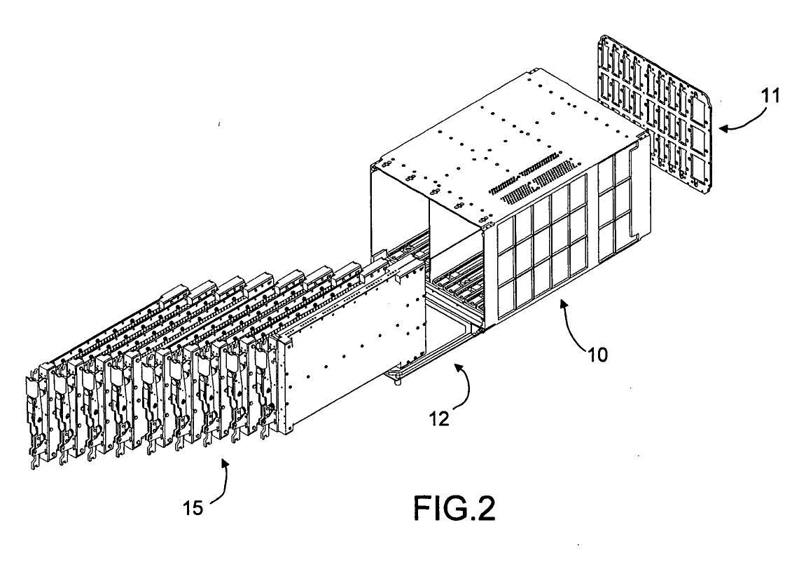

FIG. 2 shows a modular-type electronic apparatus case 10 of the prior art employed, for example, in the military aircraft field.

The case 10 is also of parallelepipedal shape. A first face 11 of the case has several openings for housing electrical connectors. The first face is intended to be placed in contact with a receiving rack fastened to an aircraft. A second face of the case 10, lying opposite the first face, may be temporarily removed. The case 10 contains one or more electronic apparatus items, the components of which are mounted on one or more printed circuit cards 15 placed perpendicular to the first and second faces of the case 10. The electronic apparatus item or items, the components of which are mounted on printed circuit boards 15, exchange electrical signals with other electronic apparatus items housed in other cases (not shown in FIG. 2) and consequently require them to be electrically connected passing through the environment external to the case 10.

The faces of the case other than the first and second faces constitute a one-piece assembly. This assembly is produced by lost-wax molding in aluminium alloy. Two of the faces of the assembly, facing each other, have a constant thickness and include orifices for allowing the flow of a heat-transfer fluid, for example air, inside the case in order to remove the heat dissipated by the electronic apparatus in the case. Two other faces of the assembly, also facing each other, have an irregular thickness. In certain areas, the thickness of the faces is reduced in order to limit the total mass of the case.

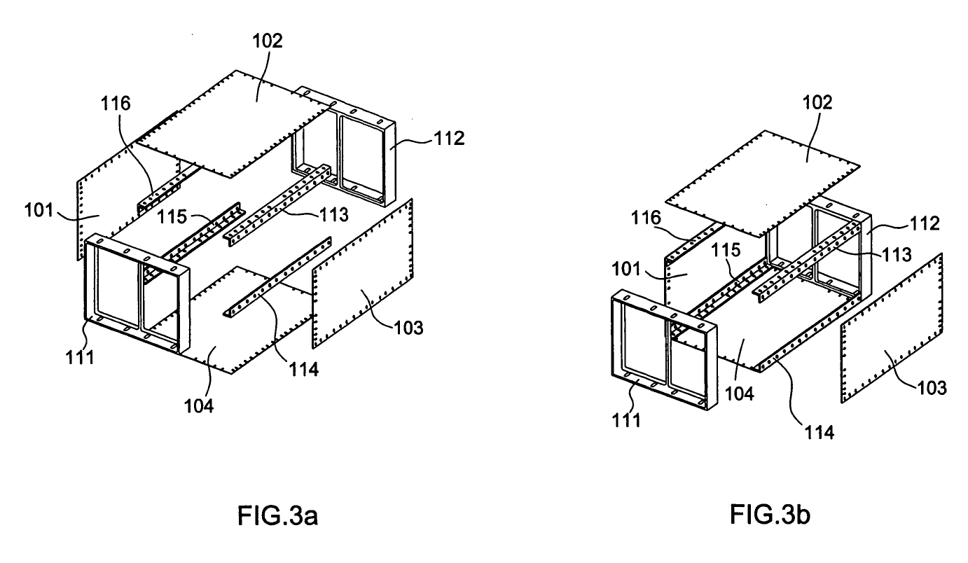

FIG. 3 shows a case 100 according to the invention in exploded view. The case, of parallelepipedal shape, comprises four walls 101, 102, 103, 104 made of sheets of a first metallic material mounted on reinforcements 111, 112, 113, 114, 115, 116. The reinforcements make up a front frame 111, a rear frame 112, of rectangular shape, which are made of a second material, and four metal cross-members 113, 114, 115, 116 of equal length, joining the corners of the rectangle formed by the front frame 111 and the rear frame 112.

The first metallic material constituting the walls is a magnesium alloy. For example one wall may be made of a sheet bearing the reference AZ 31 HP, from the French manufacturer MEL. For example, the walls have a thickness of 1.5 millimeters.

The frames 111, 112 are for example obtained by gravity-fed plaster casting with the alloy AZ91E. The frames 111, 112 are bulkier than the walls—their average thickness is for example 3 millimeters.

The cross-members 113, 114, 115, 116 shown in FIG. 3a are metal parts produced by machining. In FIG. 3, the cross-members 113, 114, 115, 116 have a right-angled or “L-shaped” cross section and are drilled so as to reduce their weight; their cross section may also be rectangular. The cross-members 113, 114, 115, 116 serve to join the walls to the four lateral corners of the cavity performed by the case.

Advantageously, the frames are obtained by lost-wax molding.

Advantageously, the cross-members 113, 114, 115, 116 have a rectangular cross section.

Advantageously, the cross-members 113, 114, 115, 116 have a right-angled cross section.

Advantageously, the cast magnesium alloy constituting the frames 111, 112 has a magnesium content of greater than 90%.

Advantageously, the magnesium alloy constituting the sheet has a magnesium content of greater than 90%.

The structure of the cases according to the invention is a hybrid structure—it combines mechanical elements (reinforcements and walls) that may be made by different means and consist of different means.

FIG. 3b shows a partially assembled case 100 according to the invention. The mechanical elements are assembled together by adhesively bonding the walls to the edges of the frames. The adhesive employed for assembling the walls to the frames is for example a thermally and electrically conductive adhesive. The walls are joined together by bonding to the cross-members. The rigidity of the case is provided by the frames.

Advantageously, the metal walls 101, 102, 103, 104 are mounted on the reinforcements by a conductive adhesive.

The electrical continuity of the case is provided by rivets made of aluminum alloy that pass through both the walls and the frames. Several rivets are employed in order to link a wall to a frame.

Advantageously, the case includes metal rivets passing through the frames 11, 112 and the metal walls 101, 102, 103, 104.

Advantageously, the metal rivets are made of an aluminum alloy.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. An electronic apparatus case, comprising:
metal walls that are mounted on reinforcements, wherein the reinforcements comprise two frames and four cross-members of identical length that connect the two frames, wherein the frames are made of cast magnesium alloy, which is molded and/or machined, and wherein at least one of the walls is made from a magnesium alloy sheet.

2. The electronic apparatus case as claimed in claim 1, wherein the metal walls are mounted on the reinforcement by a conductive adhesive.

3. The electronic apparatus case as claimed in claim 1, wherein the frames are obtained by lost-wax molding.

4. The electronic apparatus case as claimed in claim 1, wherein the cross-members have a rectangular cross section.

5. The electronic apparatus case as claimed in claim 1, wherein the cross-members have a right-angled cross section.

6. The electronic apparatus case as claimed in claim 1, comprising metal rivets passing through the frames and the metal walls.

7. The electronic apparatus case as claimed in claim 6, wherein the metal rivets are made of aluminum alloy.

8. The electronic apparatus case as claimed in claim 1, wherein the cast magnesium alloy constituting the frames has a magnesium content of greater than 90%.

9. The electronic apparatus case as claimed in claim 1, wherein the magnesium alloy constituting the sheet has a magnesium content of greater than 90%.

10. The electronic apparatus case as claimed in claim 1, wherein the cross-members are made of aluminum alloy and are produced by machining.

11. The electronic apparatus case as claimed in claim 2, wherein the frames are obtained by lost-wax molding.

12. The electronic apparatus case as claimed in claim 2, wherein the cross-members have a rectangular cross section.

13. The electronic apparatus case as claimed in claim 2, wherein the cross-members have a right-angled cross section.

14. The electronic apparatus case as claimed in claim 2, comprising metal rivets passing through the frames and the metal walls.

15. The electronic apparatus case as claimed in claim 2, wherein the metal rivets are made of aluminum alloy.

16. The electronic apparatus case as claimed in claim 2, wherein the cast magnesium alloy constituting the frames has a magnesium content of greater than 90%.

17. The electronic apparatus case as claimed in claim 2, wherein the magnesium alloy constituting the sheet has a magnesium content of greater than 90%.

18. The electronic apparatus case as claimed in claim 11, wherein the cross-members have a rectangular cross section.

19. The electronic apparatus case as claimed in claim 18, wherein the cross-members have a right-angled cross section.

20. The electronic apparatus case as claimed in claim 19, wherein the magnesium alloy constituting the sheet has a magnesium content of greater than 90%.
